(19) United States
(12) Patent Application Publication
(10) Pub. No.: US 2026/0101796 A1
(43) Pub. Date: Apr. 9, 2026

(54) SEMICONDUCTOR DEVICE AND METHOD OF MANUFACTURING THE SAME

(71) Applicant: Renesas Electronics Corporation, Tokyo (JP)

(72) Inventor: Koichi ANDO, Tokyo (JP)

(21) Appl. No.: 19/304,875

(22) Filed: Aug. 20, 2025

(30) Foreign Application Priority Data
Oct. 4, 2024 (JP) 2024-174921

(51) Int. Cl. H01L 23/00

(52) U.S. Cl. CPC H10W 72/20; H10W 72/012; H10W 72/019; H10W 72/90; H10W 72/01255; H10W 72/01257; H10W 72/01938; H10W 72/222; H10W 72/227; H10W 72/248; H10W 72/252; H10W 72/29; H10W 72/926; H10W 72/936; H10W 72/9415; H10W 72/952; H10W 90/724

(57) ABSTRACT

A semiconductor device capable of suppressing a bonding defect between a bump of a semiconductor chip and a land of a wiring substrate is provided. The semiconductor device includes the semiconductor chip. The semiconductor chip includes a semiconductor substrate, a wiring layer, a protective film, a first bump and a second bump. The wiring layer is formed on the semiconductor substrate and has a first bonding pad and a second bonding pad. The first bonding pad has a first upper surface. The second bonding pad has a second upper surface. The protective film is formed on the wiring layer so as to cover the first bonding pad and the second bonding pad. The protective film has a first opening portion overlapping the first bonding pad and penetrating through the protective film, and a second opening portion overlapping the second bonding pad and penetrating through the protective film.

### CROSS-REFERENCE TO RELATED APPLICATIONS

The disclosure of Japanese Patent Application No. 2024-174921 filed on Oct. 4, 2024, including the specification, drawings and abstract is incorporated herein by reference in its entirety.

### BACKGROUND

This disclosure relates to a semiconductor device and a method of manufacturing a semiconductor device.

There are disclosed techniques listed below.

### [Patent Document 1] Japanese Unexamined Patent Application Publication No. 2019-75442

Patent Document 1 discloses a semiconductor device having a semiconductor chip mounted on a wiring substrate by a flip-chip bonding method.

### SUMMARY

In recent years, as the integration of a semiconductor device is to be high, it tends to increase the number of terminals (bonding pads) provided on a semiconductor chip. On the other hand, there is a demand for miniaturization of a mounting substrate on which the semiconductor device is mounted. Therefore, the present inventor has considered reducing the size of each of certain bumps among a plurality of bumps that electrically connects the wiring substrate and the semiconductor chip with each other, in the semiconductor device in which the semiconductor chip is mounted on the wiring substrate by the flip-chip bonding method, like Patent Document 1. As a result, it is found that there is a risk that a bonding defect occurs between the wiring substrate and the semiconductor chip. Other problems and novel features will become apparent from the description and accompanying drawings of this specification.

A semiconductor device according to this disclosure includes a semiconductor chip. The semiconductor chip includes a semiconductor substrate, a wiring layer, a protective film, a first bump and a second bump. The wiring layer is formed on the semiconductor substrate and has a first bonding pad and a second bonding pad. The first bonding pad has a first upper surface. The second bonding pad has a second upper surface. The protective film is formed on the wiring layer so as to cover the first bonding pad and the second bonding pad. The protective film has a first opening portion overlapping the first bonding pad and penetrating through the protective film, and a second opening portion overlapping the second bonding pad and penetrating through the protective film. The first bump includes: a first seed layer formed on the first upper surface; a first pillar formed on the first seed layer and having a third upper surface; and a first conductive member formed on the third upper surface. The second bump includes: a second seed layer formed on the second upper surface; a second pillar formed on the second seed layer and having a fourth upper surface; and a second conductive member formed on the fourth upper surface. A distance between the first upper surface and the third upper surface is larger than a distance between the second upper surface and the fourth upper surface.

According to the semiconductor device of this disclosure, the bonding defect between the bump of the semiconductor chip and the land of the wiring substrate can be suppressed.

### BRIEF DESCRIPTION OF THE DRAWINGS

FIG. 1 is a plan view of a semiconductor chip CHP in a semiconductor device DEV1.

FIG. 2 is a cross-sectional view of the semiconductor chip CHP at line II-II in FIG. 1.

FIG. 3 is an enlarged cross-sectional view of the semiconductor chip CHP in the semiconductor device DEV1.

FIG. 4 is a cross-sectional view of the semiconductor device DEV1.

FIG. 5 is a diagram of a manufacturing process of the semiconductor device DEV1.

FIG. 6 is a first cross-sectional view explaining a semiconductor chip preparing step S1 in the manufacturing process of the semiconductor device DEV1.

FIG. 7 is a second cross-sectional view explaining the semiconductor chip preparing step S1 in the manufacturing process of the semiconductor device DEV1.

FIG. 8 is a third cross-sectional view explaining the semiconductor chip preparing step S1 in the manufacturing process of the semiconductor device DEV1.

FIG. 9 is a fourth cross-sectional view explaining the semiconductor chip preparing step S1 in the manufacturing process of the semiconductor device DEV1.

FIG. 10 is a fifth cross-sectional view explaining the semiconductor chip preparing step S1 in the manufacturing process of the semiconductor device DEV1.

FIG. 11 is a sixth cross-sectional view explaining the semiconductor chip preparing step S1 in the manufacturing process of the semiconductor device DEV1.

FIG. 12 is a seventh cross-sectional view explaining a wiring substrate preparing step S2 in the manufacturing process of the semiconductor device DEV1.

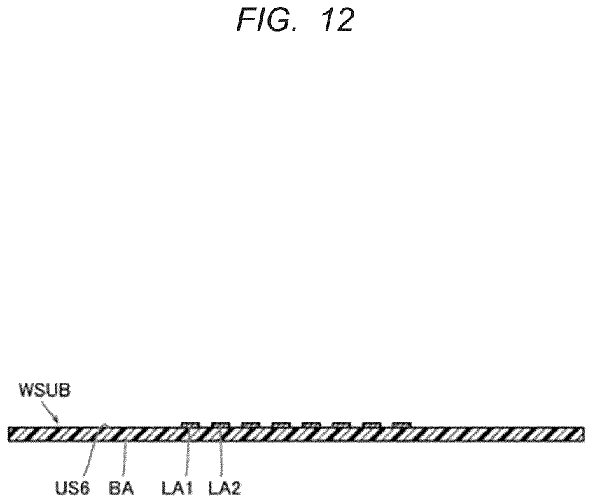

FIG. 13 is a eighth cross-sectional view explaining a semiconductor chip mounting step S3 in the manufacturing process of the semiconductor device DEV1.

FIG. 14 is an enlarged cross-sectional view of a semiconductor chip CHP in a semiconductor device DEV2.

FIG. 15 is an enlarged cross-sectional view of a semiconductor chip CHP in a semiconductor device DEV3.

FIG. 16 is a cross-sectional view explaining a semiconductor chip preparing step S1 in a manufacturing process of the semiconductor device DEV3.

FIG. 17 is an enlarged cross-sectional view of a semiconductor chip CHP in a semiconductor device DEV4.

FIG. 18 is an enlarged cross-sectional view of a semiconductor chip CHP in a semiconductor device DEV5.

FIG. 19 is a plan view of the semiconductor chip CHP in the semiconductor device DEV5.

FIG. 20 is a cross-sectional view explaining a semiconductor chip mounting process S3 in a manufacturing process of the semiconductor device DEV5.

FIG. 21 is an enlarged cross-sectional view of a semiconductor chip CHP in a semiconductor device DEV6.

### DETAILED DESCRIPTION

The details of the embodiments of the present disclosure will be described with reference to the drawings. In the following drawings, the same or corresponding parts are denoted by the same reference numerals, and redundant descriptions are not repeated.

### First Embodiment

A semiconductor device DEV1 according to the first embodiment will be described.

### Configuration of Semiconductor Device DEV1

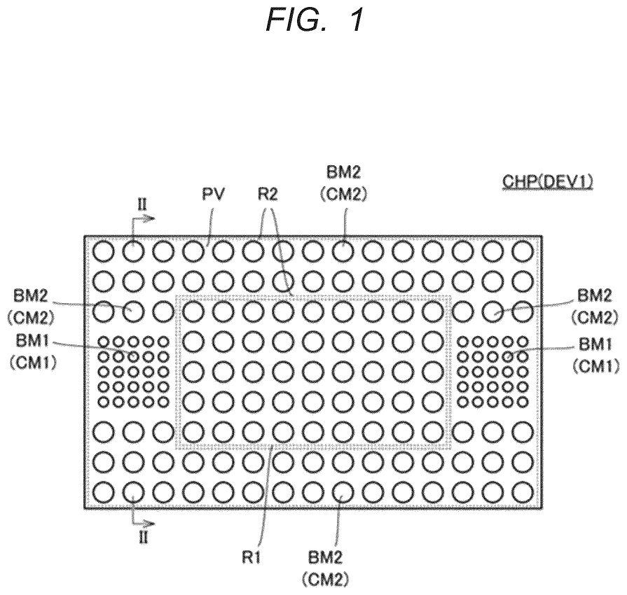

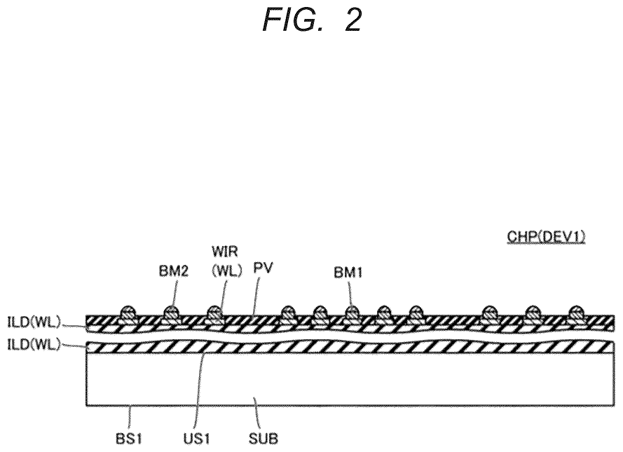

As shown in FIGS. 1, 2, and 3, the semiconductor device DEV1 includes a semiconductor chip CHP. The semiconductor chip CHP includes a semiconductor substrate SUB, a wiring layer WL, a protective film PV, and a plurality of bumps BM1 and BM2.

The semiconductor substrate SUB has an upper surface US1 and a lower surface BS1 located opposite the upper surface US1. The semiconductor substrate SUB is made of, for example, mono-crystalline silicon. That is, the semiconductor substrate SUB is a so-called silicon substrate. The wiring layer WL is formed on the semiconductor substrate SUB. More specifically, the wiring layer WL is formed on the upper surface US1. Although not shown in detail, the wiring layer WL includes a plurality of insulating layers ILD and a plurality of wiring layers. The plurality of insulating layers ILD and the plurality of wiring layers are alternately stacked one layer at a time. However, a plurality of wirings WIR provided in the uppermost wiring layer is not covered by the insulating film composing the insulating layer ILD. The insulating film composing the insulating layer ILD is made of, for example, silicon oxide. The wiring WIR is made of, for example, aluminum or an aluminum alloy.

The plurality of wirings WIR provided in the uppermost wiring layer includes a bonding pad BP1 and a bonding pad BP2. The bonding pad BP1 has an upper surface US2. The bonding pad BP2 has an upper surface US3.

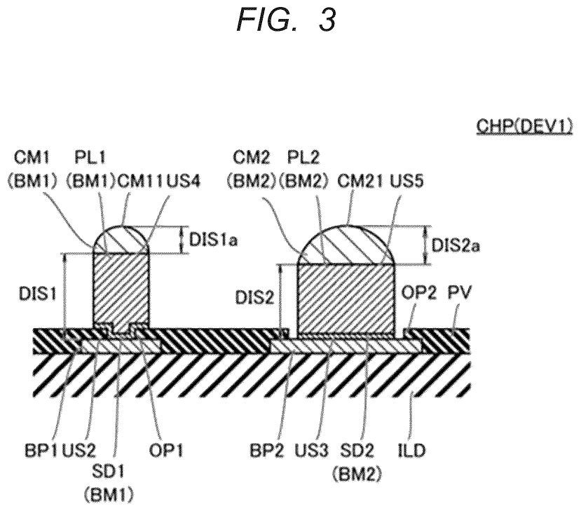

The protective film PV is formed on the wiring layer WL so as to cover the wiring WIR (bonding pads BP1 and BP2) provided in the uppermost wiring layer. An opening portion OP1 and a opening portion OP2 are formed in the protective film PV. The opening portion OP1 overlaps the bonding pad BP1 in plan view. The opening portion OP2 overlaps the bonding pad BP2 in plan view. Each of the opening portion OP1 and the opening portion OP2 penetrates through the protective film PV. A part of the upper surface US2 is exposed from the protective film PV within the opening portion OP1. A part of the upper surface US3 is exposed from the protective film PV within the opening portion OP2. In the first embodiment, as shown in FIG. 3, the size (opening area) of the opening portion OP1 is smaller than the size (opening area) of the opening portion OP2. The protective film PV is made of, for example, silicon oxide film, silicon nitride, or a laminated film of silicon oxide film and silicon nitride film.

The bump BM1 includes a seed layer SD1, a pillar PL1, and a conductive member CM1. As shown in FIG. 3, the seed layer SD1 is formed not only on the upper surface US2 but also on the protective film PV located around the opening portion OP1. Therefore, a portion, which is exposed from the protective film PV within the opening portion OP1, of the bonding pad PD1 is covered by the seed layer SD1. The seed layer SD1 is a laminated film having, for example, a titanium layer and a copper layer formed on the titanium layer. The pillar PL1 is formed on the seed layer SD1. In the first embodiment, as shown in FIG. 3, the pillar PL1 is a cylinder. The pillar PL1 has an upper surface US4. That is, in the first embodiment, the planar shape of the upper surface US4 of the pillar PL1 is a circular. The pillar PL1 is made of, for example, copper or a copper alloy. The conductive member CM1 is formed on the upper surface US4 of the pillar PL1. The top surface of the conductive member CM1 is formed in arc shape in cross-sectional view. The conductive member CM1 is made of, for example, tin-silver-based solder alloy.

The bump BM2 includes a seed layer SD2, a pillar PL2, and a conductive member CM2. As shown in FIG. 3, unlike the seed layer SD1, the seed layer SD2 is formed on the upper surface US2 but not on the protective film PV located around the opening portion OP1. That is, the seed layer SD2 is located inside the opening portion OP2 in plan view. In the first embodiment, as shown in FIG. 3, a part of a portion, which is exposed from the protective film PV within the opening portion OP2, of the bonding pad PD2 is exposed from the seed layer SD2. The seed layer SD2 is a laminated film having, for example, a titanium layer and a copper layer formed on the titanium layer. The pillar PL2 is formed on the seed layer SD2. In the first embodiment, the pillar PL2 is also a cylinder. The pillar PL2 has an upper surface US5. That is, in the first embodiment, the planar shape of the upper surface US5 of the pillar PL2 is also a circular. The pillar PL2 is made of, for example, copper or a copper alloy. The conductive member CM2 is formed on the upper surface US5 of the pillar PL2. The top surface of the conductive member CM2 is formed in arc shape in cross-sectional view. The conductive member CM2 is made of, for example, tin-silver-based solder alloy.

When the height from the upper surface US2 of the bonding pad BP1 to the upper surface US4 of the pillar PL1 (i.e., minimum value of distance between upper surface US2 and upper surface US4) is defined as a distance DIS1, and when the height from the upper surface US3 of the bonding pad BP2 to the upper surface US5 of the pillar PL2 (i.e., minimum value of distance between upper surface US3 and upper surface US5) is defined as a distance DIS2, as shown in FIG. 3, the distance DIS1 is larger than the distance DIS2. The size (area, diameter) of the upper surface US4 is smaller than the size (area, diameter) of the upper surface US5. That is, the diameter of the pillar PL1 is smaller than the diameter of the pillar PL2. When the height from the upper surface US4 of the pillar PL1 to the top CM11 of the conductive member CM1 (i.e., maximum value of distance between upper surface US4 and top CM11) is defined as a distance DIS1a, and when the height from the upper surface US5 of the pillar PL2 to the top CM21 of the conductive member CM2 (i.e., maximum value of distance between upper surface US5 and top CM21) is defined as a distance DIS1b, as shown in FIG. 3, the distance DIS1a is smaller than the distance DIS2a.

In the first embodiment, for example, the bump BM1 serves as a signal bump, and the bump BM2 serves as a power supply potential terminal or a reference potential terminal. The semiconductor chip CHP has, in plan view, a central region R1 (region enclosed by dotted line indicated by reference numeral R1 in FIG. 1) and an outer peripheral region R2 (region sandwiched between two dotted lines indicated by reference numeral R2 in FIG. 1). The central region R1 is located at the central portion of the semiconductor chip CHP in plan view, as shown in FIG. 1. The outer peripheral region R2 surrounds the central region R1 in plan view. In the first embodiment, the bump BM1 and the bump BM2 are located in the outer peripheral region R2.

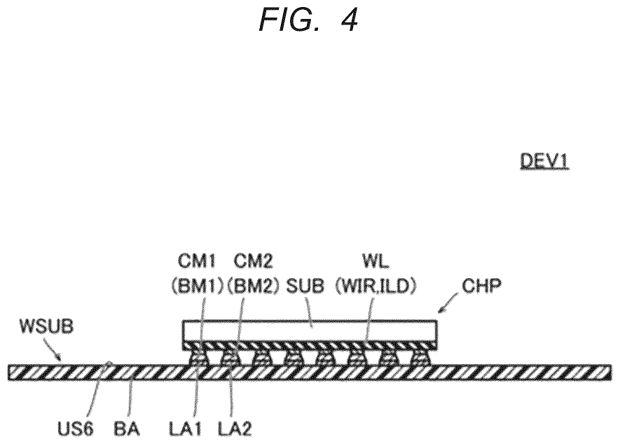

As shown in FIG. 4, the semiconductor device DEV1 further includes a wiring substrate WSUB. The wiring substrate WSUB includes a base material BA and lands (terminals) LA1 and LA2. The base material BA is made of an insulating member. The base material BA is made of, for example, glass epoxy. That is, the wiring substrate WSUB is a so-called organic substrate. The base material BA has an upper surface US6. The lands LA1 and LA2 are formed on the upper surface US6. The lands LA1 and LA2 are made of, for example, copper or a copper alloy. The semiconductor chip CHP is disposed on the wiring substrate WSUB such that the bump BM1 faces the land LA1 and such that the bump BM2 faces the land LA2. That is, the semiconductor device DEV1 according to the first embodiment is a so-called FCBGA (Flip Chip Ball Grid Array). The bump BM1 is bonded to the land LA1 via the conductive member CM1, and the bump BM2 is bonded to the land LA2 via the conductive member CM2.

### Method of Manufacturing Semiconductor Device DEV1

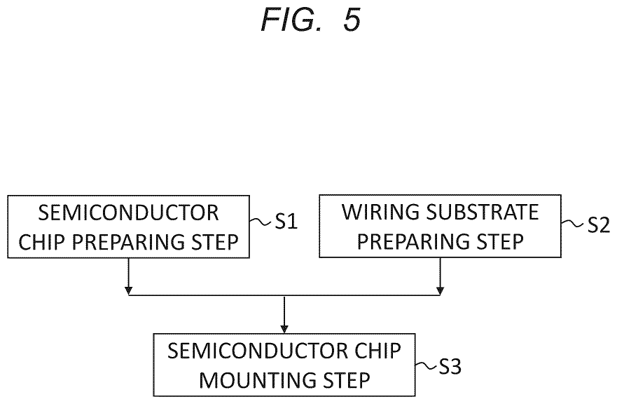

As shown in FIG. 5, a method of manufacturing the semiconductor device DEV1 includes a semiconductor chip preparing step S1, a wiring substrate preparing step S2, and a semiconductor chip mounting step S3.

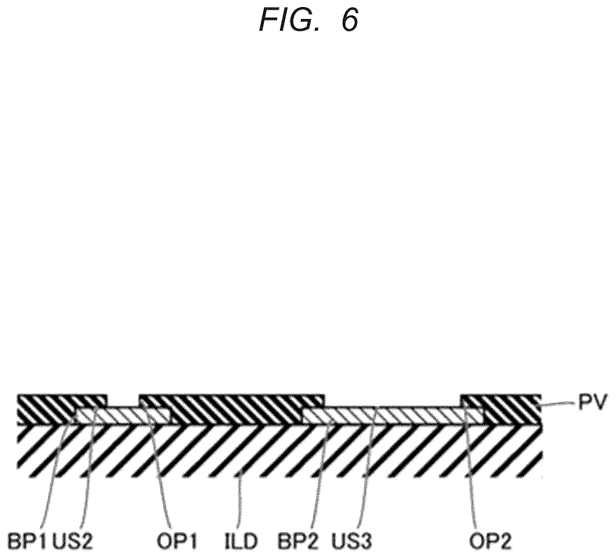

The semiconductor chip preparing step S1 will be described. First, a semiconductor wafer is prepared, on which a plurality of bonding pads (bonding pads PD1 and PD2) and a protective film PV are formed on the insulating layer ILD located at the uppermost layer of the plurality of insulating layers ILD. As shown in FIG. 6, at the stage of the semiconductor chip preparing step S1, the bump (bumps BM1 and BM2) has not yet formed on the bonding pad (bonding pads PD1 and PD2).

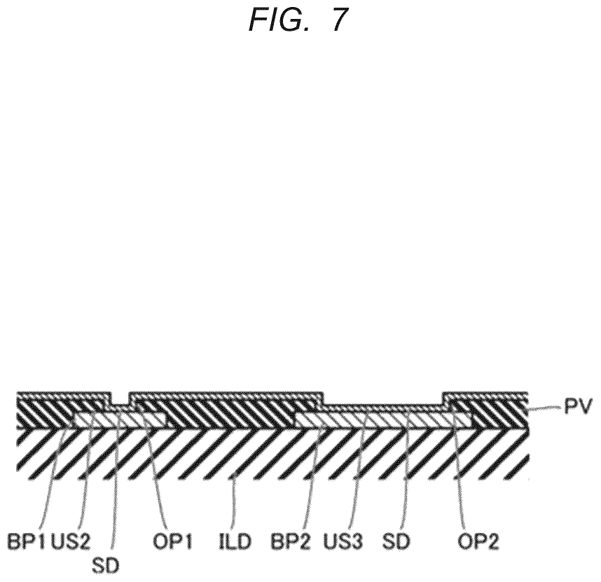

Next, as shown in FIG. 7, a seed layer SD is formed on the protective film PV, and formed on the bonding pad (bonding pads PD1 and PD2) exposed from the protective film PV within the opening portion (opening portions OP1 and OP2). In the first embodiment, the seed layer SD is formed, for example, by sputtering.

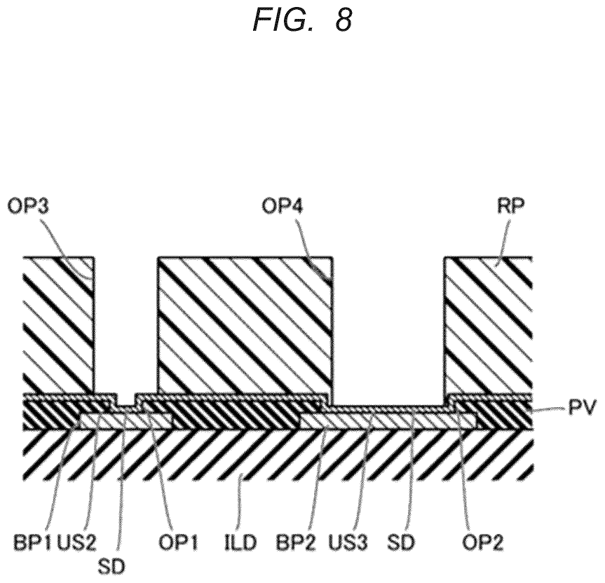

Next, as shown in FIG. 8, a resist pattern RP is formed on the seed layer SD. The resist pattern RP has an opening portion OP3 and an opening portion OP4. That is, as shown in FIG. 8, a part of the seed layer SD is exposed from the resist pattern RP within each opening portion (opening portion OP3, opening portion OP4). In the first embodiment, the resist pattern RP is formed by photolithography, that is, by exposing and developing a photoresist applied on the seed layer SD.

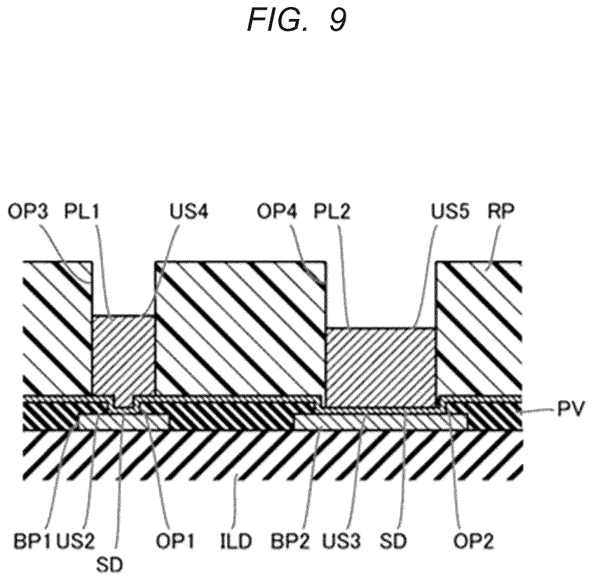

Next, as shown in FIG. 9, a pillar PL1 is formed on the seed layer SD exposed from the resist pattern RP within the opening portion OP3, and a pillar PL2 is formed on the seed layer SD exposed from the resist pattern RP within the opening portion OP4. Here, in the first embodiment, the pillars PL1 and PL2 are formed by an electrolytic plating method. The seed layer SD exposed from the resist pattern RP within the opening portion OP3 is formed not only on the upper surface US2 but also on the protective film PV located around the opening portion OP1. On the other hand, the seed layer SD exposed from the resist pattern RP within the opening portion OP4 is formed on the upper surface US3 but not on the protective film PV located around the opening portion OP2. Therefore, the pillar PL2 formed within the opening portion OP4 of the resist pattern RP does not have a portion located on the protective film PV. As a result, as shown in FIG. 9, the upper surface US5 of the pillar PL2 becomes lower than the height of the upper surface US4 of the pillar PL1.

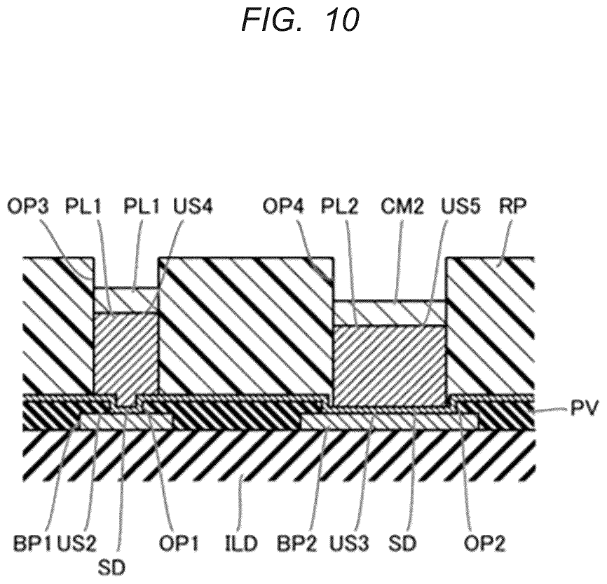

Next, as shown in FIG. 10, a conductive member CM1 and a conductive member CM2 are formed on the pillar PL1 and the pillar PL2, respectively, by an electrolytic plating method. After the conductive members CM1 and CM2 are formed, the resist pattern RP is removed. At this stage, the upper surface of each of the conductive member CM1 and the conductive member CM2 is flat, and the thickness of the conductive member CM1 is the same as that of the conductive member CM2.

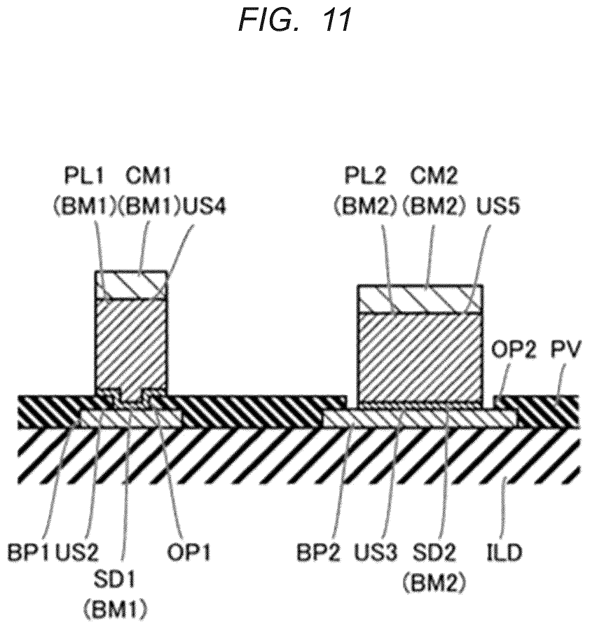

Next, as shown in FIG. 11, the seed layer SD located under the resist pattern RP is removed by etching. As a result, the seed layer SD located under the pillar PL1 becomes the seed layer SD1, and the seed layer SD located under the pillar PL2 becomes the seed layer SD2. Subsequently, by reflow (melting process), the conductive member CM1 and the conductive member CM2 are melted, and the top surface of each of the conductive member CM1 and the conductive member CM2 is formed in an arc shape due to the surface tension during the melting process as shown in FIG. 3. Since the area of the upper surface US4 is smaller than the area of the upper surface US5, at this stage, the distance (distance DIS1a) between the top CM11 of the conductive member CM1 and the upper surface US4 becomes smaller than the distance (distance DIS2a) between the top CM21 of the conductive member CM2 and the upper surface US5. Then, for example, by cutting the semiconductor wafer using a dicing blade, a semiconductor chip CHP having the structure shown in FIGS. 1 to 3 is prepared (obtained).

The wiring substrate preparing step S2 will be described. First, a wiring substrate WSUB having a base material BA and lands LA1 and LA2 is prepared. Note that the wiring substrate WSUB of the first embodiment also has lands on the lower surface of the base material BA located on the opposite side of the upper surface US6, although not shown.

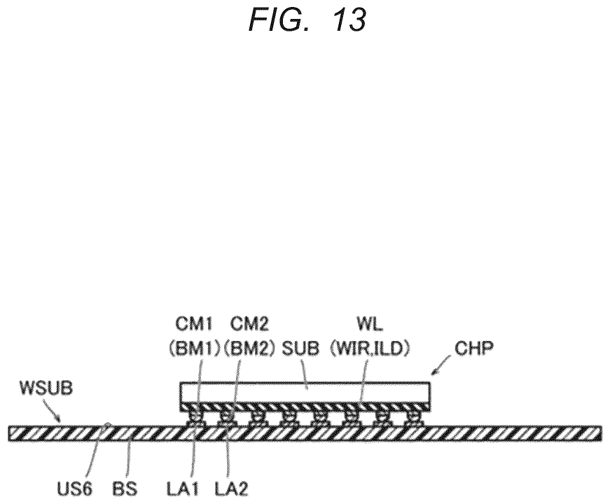

The semiconductor chip mounting step S3 will be described. As shown in FIG. 13, the semiconductor chip CHP is mounted on the wiring substrate WSUB such that the upper surface US1 of the semiconductor substrate SUB constituting the semiconductor chip CHP faces the upper surface US6 of the wiring substrate WSUB. More specifically, the semiconductor chip CHP is mounted on the wiring substrate WSUB such that the bump BM1 faces the land LA1 and the bump BM2 faces the land LA2. Then, reflow is performed. As a result, the conductive member CM1 melts and the bump BM1 and the land LA1 are bonded to each other, and the conductive member CM2 melts and the bump BM2 and the land LA2 are bonded to each other. Furthermore, although not shown, an underfill resin is supplied between the semiconductor chip CHP and the wiring substrate WSUB to seal the bonding portion between each bump and each land. Thus, the structure of the semiconductor device DEV1 shown in FIG. 4 is formed.

### Effect of Semiconductor Device DEV1

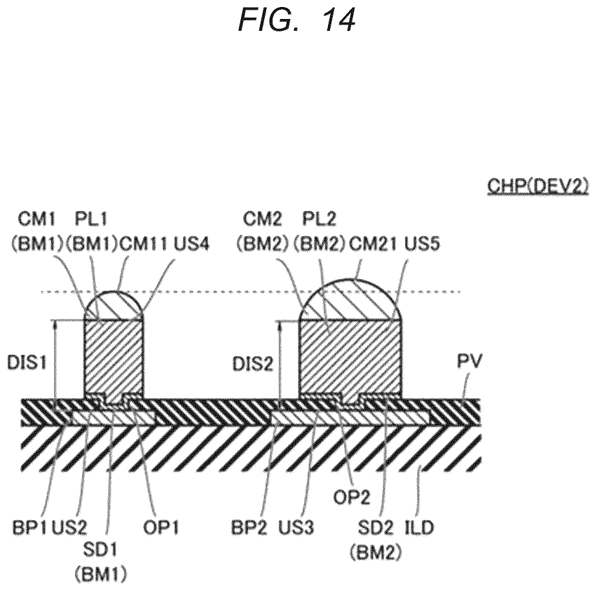

As shown in FIG. 14, in the semiconductor chip CHP of the semiconductor device DEV2 according to the comparative example, the size (opening area) of the opening portion OP1 is substantially the same as the size (opening area) of the opening portion OP2. Also, in the semiconductor chip CHP of the semiconductor device DEV2, similar to the seed layer SD1, the seed layer SD2 is formed not only on the upper surface US3 but also on the protective film PV located around the opening portion OP2. As a result, in the semiconductor chip CHP of the semiconductor device DEV2, the distance DIS1 is substantially the same as the distance DIS2. In these respects, the configuration of the semiconductor device DEV2 differs from the configuration of the semiconductor device DEV1.

Furthermore, in the semiconductor chip CHP2 of the semiconductor device DEV2, in order to arrange multiple bumps at high density, similar to the semiconductor chip CHP of the semiconductor device DEV1, the size (diameter) of the bump BM1 is smaller than the size (diameter) of the bump BM2. That is, in the semiconductor chip CHP of the semiconductor device DEV2, while the distance DIS1 is substantially the same as the distance DIS2, the size (area) of the upper surface US4 on which the conductive member CM1 is formed is made smaller than the area of the upper surface US5 on which the conductive member CM2 is formed. As a result, when reflow is performed, as shown in FIG. 14, the top CM21 of the conductive member CM2 protrudes more than the top CM11 of the conductive member CM1. Therefore, it is difficult for the conductive member CM1 to contact the land LA1 during the semiconductor chip mounting step S3, and thus, it may cause the bonding defect between the bump BM1 and the land LA1. Note that in FIG. 14, the position of the top of the conductive member CM1 is indicated by a dotted line.

On the other hand, in the semiconductor chip CHP of the semiconductor device DEV1, similar to the semiconductor chip CHP of the semiconductor device DEV2, the maximum value of the distance (distance DIS2a) between the top CM21 of the conductive member CM2 and the upper surface US5 becomes larger than the maximum value of the distance (distance DIS1a) between the top CM11 of the conductive member CM1 and the upper surface US4. However, in the semiconductor chip CHP of the semiconductor device DEV1, since the distance DIS2 is smaller than the distance DIS1, the top CM21 of the conductive member CM2 is less likely to protrude more than the top CM11 of the conductive member CM1. Therefore, according to the semiconductor device DEV1, it is possible to suppress the occurrence of the bonding defect between the bump BM1 and the land LA1.

### Second Embodiment

The semiconductor device DEV3 according to the second embodiment will be described. Here, the differences from the semiconductor device DEV1 will be mainly described, and repetitive descriptions will not be repeated.

### Configuration of Semiconductor Device DEV3

The semiconductor device DEV3 includes a semiconductor chip CHP and a wiring substrate WSUB. In this respect, the configuration of the semiconductor device DEV3 is common to the configuration of the semiconductor device DEV1.

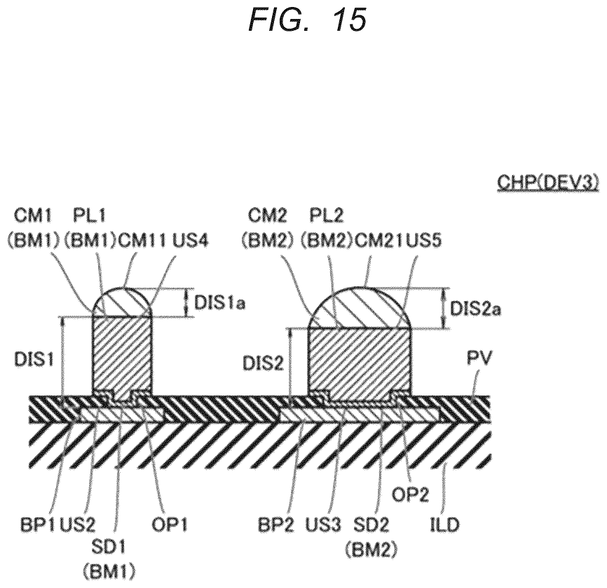

As shown in FIG. 15, similar to the semiconductor chip CHP of the semiconductor device DEV1, in the semiconductor chip CHP of the semiconductor device DEV3, the seed layer SD2 is formed not only on the upper surface US5 but also on the protective film PV located around the opening portion OP2. Note that in the semiconductor chip CHP of the semiconductor device DEV3, similar to the semiconductor chip CHP of the semiconductor device DEV1, the opening area of the opening portion OP2 is larger than the opening area of the opening portion OP1. More specifically, the area in plan view of the seed layer SD2 located inside the opening portion OP2 is, for example, 0.8 times or more of the area in plan view of the seed layer SD2 including the portion located outside the opening portion OP2, and 0.9 times or less of the area in plan view of the seed layer SD2 including the portion located outside the opening portion OP2.

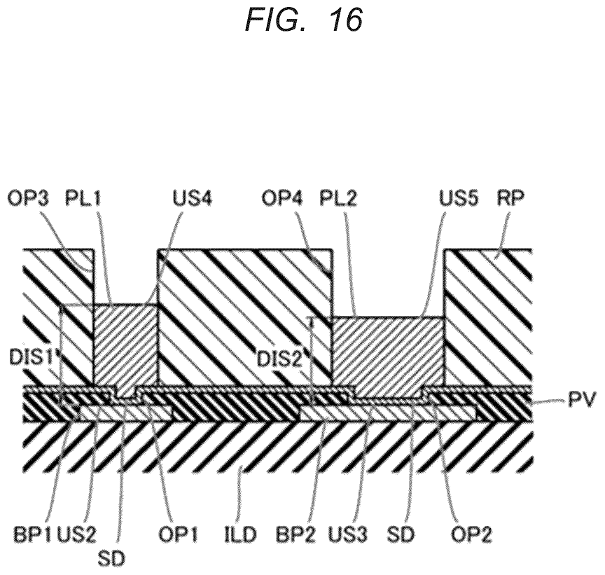

As shown in FIG. 16, in the semiconductor chip CHP of the semiconductor device DEV3, the seed layer SD exposed from the opening portion OP4 is formed on the upper surface US5 and on the protective film PV located around the opening portion OP2. However, since the size (opening area) of the opening portion OP2 is larger than the size (opening area) of the opening portion OP1, in the semiconductor chip CHP of the semiconductor device DEV3, the pillar PL2 is formed such that the distance DIS2 becomes smaller than the distance DIS1.

### Effect of Semiconductor Device DEV3

In the semiconductor chip CHP of the semiconductor device DEV3, similar to the semiconductor chip CHP of the semiconductor device DEV1, the maximum distance (distance DIS2a) between the top CM21 of the conductive member CM2 and the upper surface US5 becomes larger than the maximum distance (distance DIS1a) between the top CM11 of the conductive member CM1 and the upper surface US4. However, in the semiconductor chip CHP of the semiconductor device DEV3, similar to the semiconductor chip CHP of the semiconductor device DEV1, since the distance DIS2 is smaller than the distance DIS1, the top CM21 of the conductive member CM2 is less likely to protrude more than the top CM11 of the conductive member CM1. Therefore, according to the semiconductor device DEV3, it is possible to suppress the occurrence of the bonding defect between the bump BM1 and the land LA1.

### Modified Example of Second Embodiment

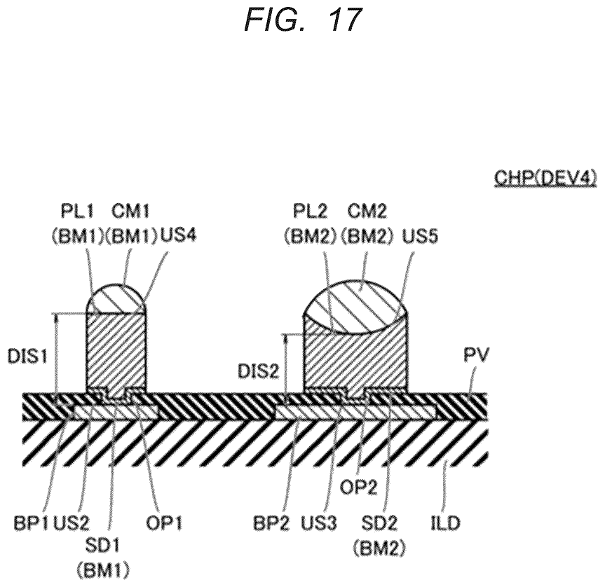

The semiconductor device DEV3 related to the modified example is referred to as semiconductor device DEV4. As shown in FIG. 17, in the semiconductor chip CHP of the semiconductor device DEV4, the upper surface US5 forms a convex curve downward in cross-sectional view. Also, in the semiconductor chip CHP of the semiconductor device DEV4, the difference in size (opening area) between the opening portion OP2 and the opening portion OP1 is smaller compared to the semiconductor chip CHP of the semiconductor device DEV3. That is, in the semiconductor chip CHP of the semiconductor device DEV4, the size of the opening portion OP2 is substantially the same as the size of the opening portion OP1.

In the manufacturing process of the semiconductor chip CHP of the semiconductor device DEV1 and the semiconductor chip CHP of the semiconductor device DEV3, additives are included in the plating solution used to form pillars PL1 and PL2. This results in the upper surfaces US4 and US5 becoming flat. In the manufacturing process of the semiconductor chip CHP of the semiconductor device DEV4, the concentration (content) of additives in the plating solution used to form pillars PL1 and PL2 is lower compared to semiconductor devices DEV1 and DEV3. Therefore, the upper surfaces US4 and US5 are less likely to be flattened, and particularly, the upper surface US5, which has a larger area than the upper surface US4, forms a convex curve downward in cross-sectional view. As a result, in the semiconductor chip CHP of the semiconductor device DEV4, the distance DIS2 becomes smaller than the distance DIS1.

### Third Embodiment

The semiconductor device DEV5 according to the third embodiment will be described. Here, the differences from the semiconductor device DEV1 will be mainly explained, and repetitive descriptions will not be repeated.

### Configuration of Semiconductor Device DEV5

The semiconductor device DEV5 includes a semiconductor chip CHP and a wiring substrate WSUB. In this regard, the configuration of the semiconductor device DEV5 is common with the configuration of the semiconductor device DEV1.

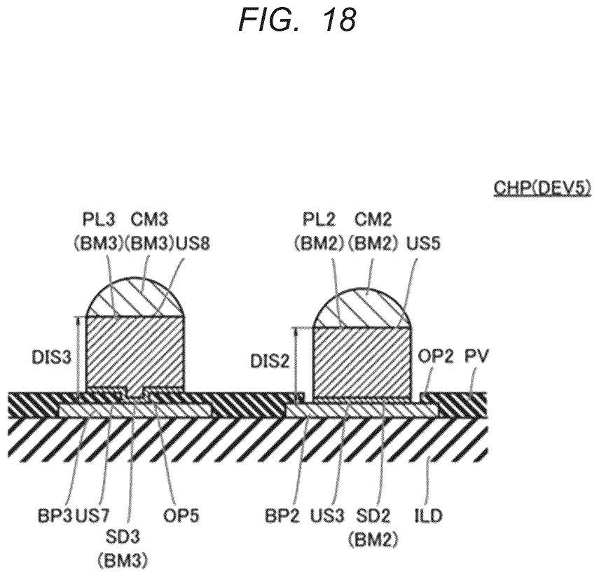

As shown in FIG. 18, the semiconductor chip CHP of the semiconductor device DEV5 has not only the above-mentioned bumps BM1 and BM2 but also a bump BM3. In the semiconductor chip CHP of the semiconductor device DEV5, a plurality of wiring WIR provided in the uppermost wiring layer further have a bonding pad BP3. The bonding pad BP3 has an upper surface US7. In the semiconductor chip CHP of the semiconductor device DEV5, an opening portion OP5 is formed in the protective film PV. The opening portion OP5 overlaps the bonding pad BP3 in a plan view and penetrates through the protective film PV. The upper surface US7 is exposed from the opening portion OP5. The opening area of the opening portion OP5 is smaller than the opening area of the opening portion OP2.

The bump BM3 further includes a seed layer SD3, a pillar PL3, and a conductive member CM3. The seed layer SD3 is formed not only on the upper surface US7 but also on the protective film PV located around the opening portion OP5. The pillar PL3 is formed on the seed layer SD3. The pillar PL3 has an upper surface US8. The area of the upper surface US8 is substantially the same as the area of the upper surface US5. That is, when the pillar PL2 and the pillar PL3 are a circular in plan view, the diameter of the pillar PL3 is substantially the same as the diameter of the pillar PL2. The conductive member CM3 is formed on the upper surface US8. The top surface of the conductive member CM3 is formed in arc shape in cross-sectional view.

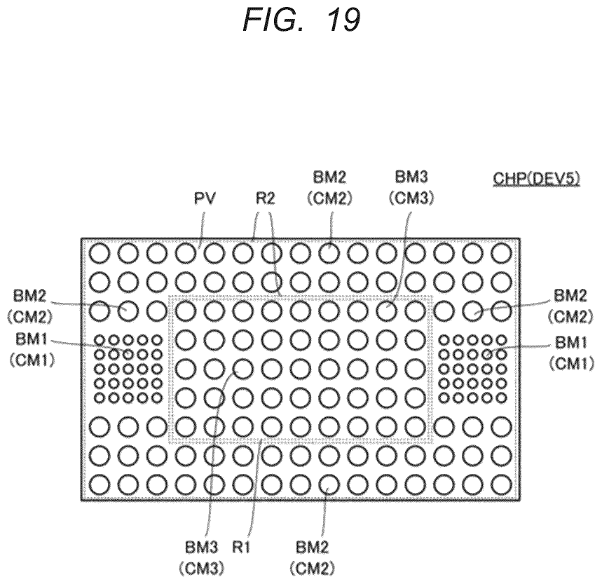

The seed layer SD3 is, for example, a laminated film having a titanium layer and a copper layer formed on the titanium layer. The pillar PL3 is made of, for example, copper or a copper alloy. The conductive member CM3 is made of, for example, tin-silver solder alloy. In the third embodiment, as shown in FIG. 19, the bump BM1 and the bump BM2 are located in the outer peripheral region R2 (region sandwiched between two dotted lines indicated by reference numeral R2 in FIG. 19), while the bump BM3 is located in the central region R1 (region enclosed by a dotted line indicated by reference numeral R1 in FIG. 19). In the third embodiment, for example, the bump BM1 serves as a signal bump, and the bump BM2 and the bump BM3 serve as a power supply potential terminal or a reference potential terminal. The minimum value of the distance between the upper surface US8 and the upper surface US7 is referred to as the distance DIS3. The distance DIS3 is larger than the distance DIS2.

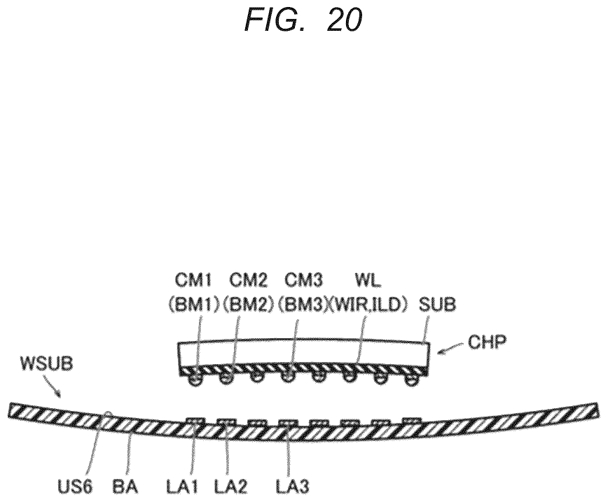

In the wiring substrate WSUB of the semiconductor device DEV5, a land LA3 is formed on the upper surface US6. In the semiconductor device DEV5, in the semiconductor chip mounting process S3, the semiconductor chip CHP is mounted on the wiring substrate WSUB such that the bump BM3 faces the land LA3. Land LA3 is made of, for example, copper or a copper alloy. As shown in FIG. 20, the wiring substrate WSUB of the semiconductor device DEV5 is warped such that the upper surface US6 shrinks in cross-sectional view. The semiconductor chip CHP of the semiconductor device DEV5 is aligned in the opposite direction to the warping direction of the wiring substrate WSUB. That is, when the semiconductor chip CHP is disposed on the wiring substrate WSUB, a surface of the semiconductor chip CHP facing the upper surface US6 shrinks as shown in FIG. 20. Therefore, the distance between the bump (here, bump BM3), which is located in the central region R1 of the semiconductor chip CHP, and the land (here, land LA3), which is to be bonded to this bump, is larger than the distance between the bump (here, bumps BM1 and BM2), which is located in the outer peripheral region R2 of the semiconductor chip CHP, and the land (here, lands LA1 and LA2), which is to be bonded to this bump. Note that in FIG. 20, the warping of the wiring substrate WSUB and the semiconductor chip CHP is exaggerated.

### Effect of Semiconductor Device DEV5

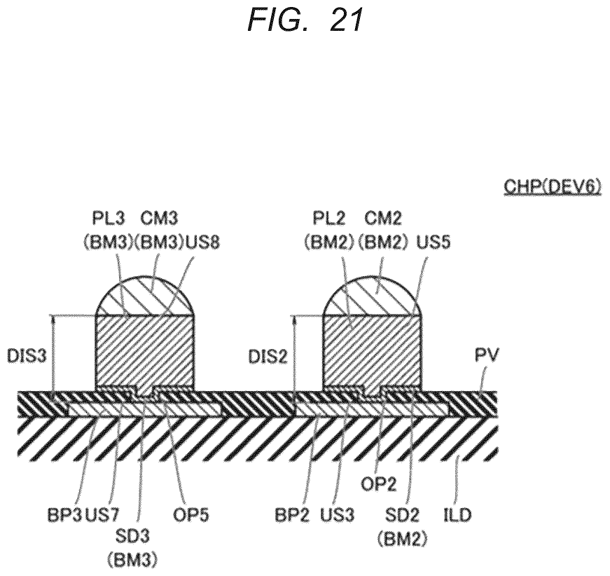

As shown in FIG. 21, in the semiconductor chip CHP of the semiconductor device DEV6 according to the comparative example, the distance DIS3 and the distance DIS2 are equal to each other. Therefore, when mounting the semiconductor chip CHP on the wiring substrate WSUB, if the wiring substrate WSUB is warped such that the upper surface US6 shrinks as shown in FIG. 20 and such that the semiconductor chip CHP is warped in the opposite direction to the wiring substrate WSUB, the conductive member CM3 may have difficulty contacting the land LA3 in the semiconductor chip mounting process S3, and thus, it may causes the bonding defect between the bump BM3 and the land LA3.

On the other hand, in the semiconductor chip CHP of the semiconductor device DEV5, the distance DIS3 is larger than the distance DIS2. Therefore, when mounting the semiconductor chip CHP on the wiring substrate WSUB, even if the wiring substrate WSUB is warped such that the upper surface US6 shrinks as shown in FIG. 20 and such that the semiconductor chip CHP is warped in the opposite direction to the wiring substrate WSUB, the conductive member CM3 can easily contact the land LA3 in the semiconductor chip mounting process S3, and thus, it is less likely for the bonding defect to occur between the bump BM3 and the land LA3.

### First Modified Example

For example, in each of the above examples, the case where one semiconductor chip CHP is mounted on the wiring substrate WSUB was described, but a plurality of semiconductor chips CHP may be mounted on the wiring substrate WSUB. In this case, one semiconductor chip CHP may, for example, transmit and receive signals via the bump BM1 with another semiconductor chip CHP.

### Second Modified Example

Also, in each of the above examples, the form in which the semiconductor chip CHP is mounted on the wiring substrate WSUB by the flip-chip bonding method was described, but it may be a form in which the semiconductor chip CHP is mounted on the wiring substrate WSUB via an interposer made of a silicon substrate or an organic substrate.

Furthermore, in each of the above examples, the bump of the semiconductor chip CHP joined to the land of the wiring substrate WSUB was described, but when using an interposer made of a silicon substrate in the second modified example, the bump of the interposer can have the same configuration as the bump of the semiconductor chip CHP.

Although the invention made by the present inventor has been specifically described based on the embodiment, the present invention is not limited to the above embodiment, and various modifications can be made without departing from the gist thereof.

What is claimed is:

1. A semiconductor device comprising:
a semiconductor chip,
wherein the semiconductor chip includes a semiconductor substrate, a wiring layer, a protective film, a first bump and a second bump,
wherein the wiring layer is formed on the semiconductor substrate and has a first bonding pad and a second bonding pad,
wherein the first bonding pad has a first upper surface,
wherein the second bonding pad has a second upper surface,
wherein the protective film is formed on the wiring layer so as to cover the first bonding pad and the second bonding pad,
wherein the protective film has:
a first opening portion overlapping the first bonding pad and penetrating through the protective film; and
a second opening portion overlapping the second bonding pad and penetrating through the protective film,
wherein the first bump includes:
a first seed layer formed on the first upper surface;
a first pillar formed on the first seed layer and having a third upper surface; and
a first conductive member formed on the third upper surface,
wherein the second bump includes:
a second seed layer formed on the second upper surface;
a second pillar formed on the second seed layer and having a fourth upper surface; and
a second conductive member formed on the fourth upper surface, and
wherein a distance between the first upper surface and the third upper surface is larger than a distance between the second upper surface and the fourth upper surface.

2. The semiconductor device according to claim 1, wherein an area of the third upper surface is smaller than an area of the fourth upper surface.

3. The semiconductor device according to claim 2,
wherein the first seed layer is formed on the first upper surface and the protective film located around the first opening portion, and
wherein the second seed layer is located inside the second opening portion in plan view.

4. The semiconductor device according to claim 2,
wherein the first seed layer is formed on the first upper surface and the protective film located around the first opening portion,
wherein the second seed layer is formed on the second upper surface and the protective film located around the second opening portion, and
wherein an opening area of the first opening portion is smaller than an opening area of the second opening portion.

5. The semiconductor device according to claim 4, wherein an area of the second seed layer located inside the second opening portion is 0.8 times or more of an area of the second seed layer including a portion located outside the second opening portion, and 0.9 times or less of the area of the second seed layer including the portion located outside the second opening portion.

6. The semiconductor device according to claim 2,
wherein the first seed layer is formed on the first upper surface and the protective film located around the first opening portion,
wherein the second seed layer is formed on the second upper surface and the protective film located around the second opening portion, and
wherein the fourth upper surface forms a convex curve downward in cross-sectional view.

7. The semiconductor device according to claim 2,
wherein the first bump serves as a signal terminal, and
wherein the second bump serves as a power supply potential terminal or a reference potential terminal.

8. The semiconductor device according to claim 1,
wherein, in plan view, the second bump is located closer to an outer peripheral edge of the semiconductor chip than the first bump, and
wherein an area of the third upper surface is equal to an area of the fourth upper surface.

9. The semiconductor device according to claim 8,
wherein the first seed layer is formed on the first upper surface and the protective film located around the first opening portion, and
wherein the second seed layer is located inside the second opening portion.

10. The semiconductor device according to claim 8,
wherein the first seed layer is formed on the first upper surface and the protective film located around the first opening portion,
wherein the second seed layer is formed on the second upper surface and the protective film located around the second opening portion, and
wherein an opening area of the first opening portion is smaller than an opening area of the second opening portion.

11. The semiconductor device according to claim 10, wherein an area of the second seed layer located inside the second opening portion is 0.8 times or more of an area of the second seed layer including a portion located outside the second opening portion, and 0.9 times or less of the area of the second seed layer including the portion located outside the second opening portion.

12. The semiconductor device according to claim 8,
wherein the first seed layer is formed on the first upper surface and the protective film located around the first opening portion,
wherein the second seed layer is formed on the second upper surface and the protective film located around the second opening portion, and
wherein the fourth upper surface forms a convex curve downward in cross-sectional view.

13. A method of manufacturing a semiconductor device, comprising:
(a) preparing a semiconductor chip and a wiring substrate,
wherein the semiconductor chip includes a semiconductor substrate, a wiring layer, a protective film, a first bump and a second bump,
wherein the wiring layer is formed on the semiconductor substrate and has a first bonding pad and a second bonding pad,
wherein the first bonding pad has a first upper surface,
wherein the second bonding pad has a second upper surface,
wherein the protective film is formed on the wiring layer so as to cover the first bonding pad and the second bonding pad,
wherein the protective film has:
a first opening portion overlapping the first bonding pad and penetrating through the protective film; and
a second opening portion overlapping the second bonding pad and penetrating through the protective film,
wherein the first bump includes:
a first seed layer formed on the first upper surface;
a first pillar formed on the first seed layer and having a third upper surface; and
a first conductive member formed on the third upper surface,
wherein the second bump includes:
a second seed layer formed on the second upper surface;
a second pillar formed on the second seed layer and having a fourth upper surface; and
a second conductive member formed on the fourth upper surface,
wherein a distance between the first upper surface and the third upper surface is larger than a distance between the second upper surface and the fourth upper surface,
wherein, in plan view, the second bump is located closer to an outer peripheral edge of the semiconductor chip than the first bump,
wherein an area of the third upper surface is equal to an area of the fourth upper surface, and
wherein the wiring substrate includes:
a base material;
a first land formed on the base material; and
a second land formed on the base material;
(b) disposing the semiconductor chip on the wiring substrate such that the first bump faces the first land and such that the second bump faces the second land;
(c) bonding the first bump to the first land via the first conductive member, and bonding the second bump to the second land via the second conductive member,
wherein when disposing the semiconductor chip on the wiring substrate, a distance between the third upper surface and the first land is larger than a distance between the fourth upper surface and the second land.
